(19) United States
(12) Patent Application Publication
(10) Pub. No.: US 2006/0220138 A1
(43) Pub. Date: Oct. 5, 2006

(54) ESD protection circuit with scalable current capacity and voltage capacity

(75) Inventors: Volker Dudek, Brackenheim (DE); Michael Graf, Leutenbach (DE); Peter Grombach, Heilbronn (DE); Manfred Klaussner, Heilbronn (DE)

Correspondence Address: MCGRATH, GEISSLER, OLDS & RICHARDSON, PLLC, P.O. BOX 1364, FAIRFAX, VA, 22038-1364, US

(73) Assignee: ATMEL GERMANY GMBH, Heilbronn (DE)

(21) Appl. No.: 11/376,139

(22) Filed: Mar. 16, 2006

(30) Foreign Application Priority Data
Mar. 18, 2005 (DE) 10 2005 013 686.9

(51) Int. Cl. H01L 29/76

(52) U.S. Cl. 257/367

(57) ABSTRACT

An ESD protection circuit includes semiconductor structures as basic elements whose electrical conductivity changes in a breakdown or avalanche manner in the presence of an applied voltage which exceeds a threshold value. The ESD protection circuit has a matrix of basic elements in which a desired current capacity can be set by specifying a number of basic elements in each row, and a desired voltage capacity can be set by specifying a number of rows.

This nonprovisional application claims priority under 35 U.S.C. § 119(a) on German Patent Application No. DE 102005013686, which was filed in Germany on Mar. 18, 2005, and which is herein incorporated by reference.

### BACKGROUND OF THE INVENTION

1. Field of the Invention

The present invention relates to an ESD protection circuit having semiconductor structures as basic elements whose electrical conductivity changes in a breakdown or avalanche manner in the presence of an applied voltage, which exceeds a threshold value.

2. Description of the Background Art

In the handling and use of integrated circuits (IC), it is necessary to protect the components and assemblies contained therein from the effects of overvoltages. In this context, overvoltages are defined as electrical signals such as those arising, for example, from the discharging of static charges, whether from persons or machine parts through an IC or from an IC through persons or machine parts. Such discharge processes are also called electrostatic discharge (ESD). If signals of this nature, whose amplitude can be several kV and in whose presence currents in the ampere range can arise, are fed to an integrated circuit, irreversible changes in its components or assemblies can occur, for example by burn-through of thin layers (thin-film burn-out), filamentation and short-circuiting of layer junctions (junction spiking), charge carrier injection in oxide layers, or oxide rupture, which under some circumstances leads to destruction of the entire IC.

A simple example of a conventional protection circuit is a Zener diode, which is electrically connected in parallel to a component or assembly to be protected and which limits the voltage dropping across the component or assembly to the value of the breakdown voltage of the Zener diode. If the breakdown voltage is exceeded by an ESD pulse, the Zener diode conducts the discharge current, which under some circumstances can be high, past the component or assembly to a reference potential.

In general, known ESD protection structures are individually designed, optimized and manufactured for narrowly defined applications, since the ESD resistance depends on the circuit to be protected and the application conditions of the circuit to be protected. In the conventional art, other voltage ranges, for example a different supply voltage or a different requirement for voltage capacity resulting from the circuit environment, require new, individually designed ESD protection structures, with the associated expense of the design and the implementation of production through a suitable semiconductor process.

### SUMMARY OF THE INVENTION

It is therefore an object of the present invention to provide an ESD protection circuit that can be adapted to predefinable conditions for voltage capacity and current capacity at a reduced cost in its design and manufacture.

This object is attained by an ESD protection circuit that has a matrix of basic elements in which a desired current capacity can be set by specifying a number of basic elements in each row, and a desired voltage capacity can be set by specifying a number of rows.

In this way, the invention makes possible ESD protection that is scalable for any desired application, building on a basic structure. Since the current capacity increases with the number of basic elements in each row, it can be set as a multiple of the current capacity of one basic element by a corresponding number of identical basic elements in each row. The same applies with regard to the voltage capacity and the number of rows. In the simplest case, each basic element can be a simple diode.

An embodiment of the invention is distinguished by an implementation of the matrix as an integrated circuit or as a part of an integrated circuit, since the circuit to be protected is also present as an integrated circuit in most applications. The ESD protection circuit can then be manufactured within the context of a single semiconductor process on one semiconductor substrate together with the circuit to be protected, which also desirably increases the packing density of integrated circuits.

Each basic element can have an anode region and a cathode region, each with predefined dimensions, each anode region can have a semiconductor material of a first conductivity type, each cathode region can have a semiconductor material of a second conductivity type, anode regions of basic elements of a row can be joined to one another with no transition, cathode regions of a row can be joined to one another with no transition, and the semiconductor material of each row can be insulated by a dielectric isolating structure from semiconductor material of each adjacent row.

By these features, a semiconductor structure is provided as a basic element suitable for integration, with which any desired number of elements of one row can be manufactured by juxtaposing regions that are joined to one another without transition (continuously). The dielectric isolating structure between individual rows leads to a behavior with respect to voltage capacity that is defined and is predictable during circuit design.

In another embodiment, parallel to each cathode region, two anode regions of the same basic element can be arranged on two of its sides, and each basic element of each row that is not located between two other basic elements can be bordered by an edge element that connects the two anode regions of the basic element to one another with no transition through an anode edge region of the same conductivity type.

These features terminate individual rows on both sides in a defined manner, and in conjunction with the aforementioned features result in a closed ring structure for the anode region that surrounds a strip-shaped cathode region. In comparison with simple parallel connections of diodes, this results in an enlarged anode area, which has an additional favorable effect on the breakdown rating and current capacity.

Another embodiment has a first wiring level with a first electrically conductive area that areally contacts the anode regions of each row, and a second electrically conductive area that is insulated from the first electrically conductive area and areally contacts the cathode regions of each row.

As a result of the areal contact, optimal current and voltage distribution is achieved in an ESD event, preventing or at least reducing local voltage and current peaks. This is especially advantageous, since current densities of several kA per square millimeter can arise in ESD events.

Another embodiment can have a second wiring level that is areally isolated from the first wiring level by a dielectric intermediate layer and can have electrically separated first and second sections, wherein the first sections (of the second wiring level) are locally connected to the first electrically conductive area (of the second wiring level) by openings in the dielectric intermediate layer filled with electrically conductive material, and the second sections (of the second wiring level) are locally connected to the second electrically conductive area (of the first wiring level) by openings filled with electrically conductive material.

These features permit connections of the anode regions and cathode regions of a row to the corresponding regions of adjacent rows that are optimal with regard to current distribution, energy dissipation, and the structuring of the wiring levels (metallization areas).

The ESD protection circuit can also have a buried dielectric layer that dielectrically insulates the matrix on a side opposing the wiring levels.

In this way, the ESD current path is limited to cross-sections located between the wiring levels and the buried layer, which optimizes the insulation between different rows.

The dielectric isolating structures can abut the buried dielectric layer.

As a desirable result, a current flow between adjacent rows that is not carried by the wiring layer is precluded, improving the predictability of the voltage capacity of the matrix when specifying the number of its rows.

The anode regions and cathode regions of a row can be isolated from one another by a dielectric isolating structure that does not abut the buried dielectric layer.

In an ESD event, the discharge current then flows through cross-sections between this dielectric isolating structure and the buried layer. The so-called snapback characteristics of the arrangement can be influenced by the dimensioning of this isolating structure. In this context, snapback characteristics are defined as a reduction in the resistance of the arrangement following a breakdown and/or at a transition of a conductive section to a low-resistance state. With a pronounced snapback characteristic, this could lead to the undesirable effect that after a breakdown, the voltage across the ESD protection circuit drops below the value of the normal operating voltage, so that an ESD event activates the conductivity of the protection circuit longer than would be required to discharge the ESD pulse. This would contradict a fundamental requirement on the ESD protection circuit, according to which the ESD protection circuit must be inactive at the normal supply voltage.

In another embodiment, the cathode region can be located in a well made of semiconductor material of the second conductivity type, located in the well on a side facing the anode there can be at least one region of the first conductivity type that is connected to the second electrically conductive area of the first wiring level in common with a region of the second conductivity type, and the anode region and the well can be connected by a semiconductor region with ohmic conductivity of the second conductivity type that is located between the buried dielectric layer and the anode region and the well.

By these features, a basic element is provided, which in an ESD event operates with the anode as collector, the region with the first conductivity type located in the well as emitter, and the region of the second conductivity type, also located in the well, as a base. As a result of the short circuit between base and emitter created by the wiring level, the arrangement initially exhibits no transistor characteristics at low voltages. Only a current flowing between the anode region and the cathode region, after breakdown occurs, creates in the well a lateral potential gradient between emitter and base that switches the transistor to the low-resistance state so that it discharges the ESD current. When the collector current is plotted over a collector-emitter voltage, the aforementioned switching process appears as a steep rise in collector current with only a weakly pronounced snapback characteristic, so that the basic element and thus also the matrix shows almost no undesirable “snapping” in the ESD voltage range.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates a first example embodiment of an ESD protection circuit together with a circuit to be protected;

FIG. 2 is a perspective representation of a basic element of an ESD protection circuit for an implementation in the form of an integrated circuit;

FIG. 3 is a characteristic curve for a basic element from FIG. 2; and

FIG. 4 is a matrix constructed of basic elements from FIG. 2 as an integrated ESD protection circuit.

### DETAILED DESCRIPTION

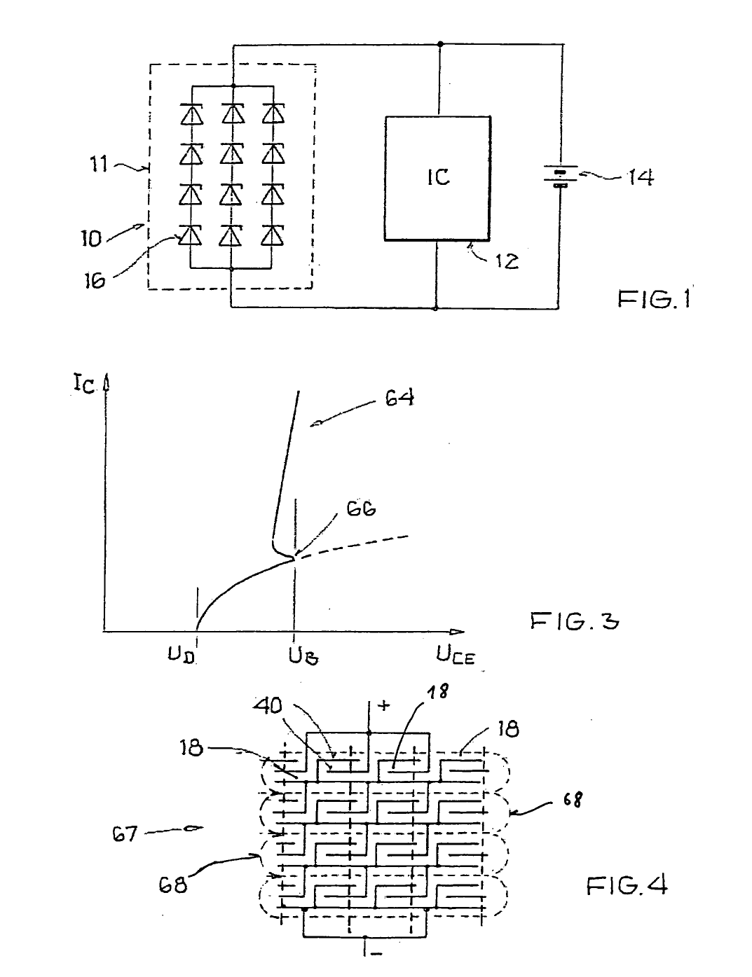

FIG. 1 shows an ESD protection circuit 10 that is electrically connected to a supply voltage source 14 in parallel with a circuit 12 to be protected. The ESD protection circuit 10 in FIG. 1 has Zener diodes as basic elements 16, which are arranged in the form of a matrix 11 with n=4 rows and m=3 columns. The Zener diodes of a column are connected in series, so that the voltage capacity of the ESD protection circuit corresponds to n times the breakdown voltage of a single basic element 16. By defining the number of basic elements 16 connected in series, it is thus possible to adjust the breakdown voltage of the overall ESD protection circuit 10 to meet the various requirements without the need to alter the individual basic elements 16. In this regard, the breakdown voltage of the ESD protection circuit 10 should be defined such that it is greater than the normal supply voltage, so that the supply voltage in normal operation is applied to the circuit 12 to be protected.

Upon the occurrence of an ESD pulse whose voltage amplitude exceeds the breakdown voltage of the ESD protection circuit 10, the breakdown voltage of each basic element 16 is exceeded in the case of symmetrical voltage distribution across the matrix 11, so that the elements can discharge the discharge current. In this context, the discharge current is distributed uniformly among the electrically parallel-connected columns of the matrix 11 in the ideal case, so that the current conductivity and thus the current capacity of the ESD protection circuit can be defined by the number of its columns, hence by the number of basic elements 16 in each row.

It is thus understood that the values of the row count n and the column count m are to be chosen as a function of the requirements for voltage capacity and current capacity, by which a scalable ESD protection for various requirements is provided based on a single type of basic element, and in which a desired current capacity can be set by specifying a number of basic elements in each row, and a desired voltage capacity can be set by specifying a number of rows.

In this context, Zener diodes represent only one embodiment of a basic element 16, which in general is embodied as a semiconductor structure whose electrical conductivity changes in a breakdown or avalanche manner in the presence of an applied voltage which exceeds a threshold value. Thus, as described in detail below, basic elements exhibiting transistor characteristics can also be used. In principle, the matrix can be constructed of separate basic elements 16. However, an implementation of the matrix as an integrated circuit or as part of an integrated circuit is preferred.

One embodiment of a basic element 18 for an integrated ESD protection circuit 10 is shown in FIG. 2. In this embodiment, the basic element 18 has at least one anode region 20, 22 and one cathode region 24, each having predefined dimensions. Each anode region 20, 22 has a semiconductor material of a first conductivity type, and the cathode region 24 has a semiconductor material of a second conductivity type.

A row of the matrix is produced by arranging multiple basic elements 18 in a row in the direction indicated by the dashed line 26. This arranging takes place during the design stage of the ESD protection circuit 10. During manufacture, the basic elements are created by conventional structuring steps of a semiconductor process in a continuous substrate of semiconductor material 30 in such a manner that anode regions 20, 22 of basic elements of a row join to one another with no transition in the direction 26 and cathode regions 24 of a row join to one another with no transition in the direction 26. Dielectric isolating structures 28 separate the semiconductor material 30 from semiconductor material of adjacent rows in the direction 32.

In the representation in FIG. 2, electrical contacting of the anode region 20, 22 and the cathode region 24 is accomplished from above by a combination of a first wiring level or metallization 34, a dielectric intermediate layer 38 provided with openings 36a, 36b, 37, and a second wiring level or metallization 40. The wiring levels 34, 40 can be made of, for example, aluminum. The openings 36a, 36b, 37 are filled with electrically conductive material, for example likewise aluminum.

The first wiring level 34 has a first electrically conductive area 42a, 42b, that areally contacts the anode regions 20, 22 of all basic elements 18 of each row. A second electrically conductive area 44 of the first wiring level 34 that is separated from the first electrically conductive area 42a, 42b, and is thus electrically insulated from the area 42a, 42b, areally contacts the cathode regions 24 of all basic elements 18 of each row.

The second wiring level 40 is areally isolated from the first wiring level 34 by the dielectric intermediate layer 38, and has first sections 46a, 46b and second sections 48a, 48b. The first sections 46a, 46b of the second wiring level 40 are locally connected to the first electrically conductive area 42a, 42b of the first wiring level 34 by openings 36a, 36b in the dielectric intermediate layer 38 that are filled with electrically conductive material, and thus connect to the anode regions 20, 22. Similarly, the second sections 48a, 48b of the second wiring level 40 are locally connected to the second electrically conductive area 44 of the first wiring level 34 by openings 37 that are filled with electrically conductive material, and thus connect to the cathode region 24.

As can easily be seen, such a basic element 18 can serve as a fundamental cell from which a row can be constructed by arranging any desired number of basic cells 18 in a row along the direction 26, wherein the electrical contact likewise continues along the direction 26. The section 48b extends somewhat beyond the right edge of the sections 46a, 46b in the direction 32, so that it bridges the right-hand dielectric isolating structure 28 in this direction 32. As a result, a section 46a of an identical basic element 18 of an adjacent row, which is to be placed adjacent in the direction 32 to the basic element 18 that is shown, is electrically connected to the section 48b of the basic element 18 that is shown, resulting in a series connection of the type represented by the columns of the matrix of basic elements 16 shown in FIG. 1.

As part of a preferred embodiment, the basic element 18 additionally has a buried dielectric layer 50, which extends over the entire matrix, and therefore dielectrically insulates the matrix on a side opposite the wiring levels 34, 40. This characteristic arises, for example, when an SOI substrate (SOI=semiconductor on insulator) is used as starting material for producing the matrix. In FIG. 2, the SOI structure results from the placement of the semiconductor material 30 on the buried dielectric layer 50, which is located on a substrate layer 51.

The aforementioned dielectric isolating structures 28 preferably extend deep enough into the semiconductor material 30 to abut the buried dielectric layer 50. In this way, complete dielectric isolation of the semiconductor material of different rows of the matrix is achieved at the depth of the semiconductor material 30, so that electrical contact and connection to various basic elements 18 takes place only in a defined manner prescribed by the geometry of the wiring levels 34, 40.

The anode regions 20, 22 and the cathode region 24 can adjoin one another directly in the semiconductor material 30, and form a diode with the pn junction thus produced. Preferably, however, at the surface of the semiconductor material of the basic element 18 adjacent to the first wiring level 34, the regions are separated from one another by at least one dielectric isolating structure 52 that does not abut the buried dielectric layer 50. Such an isolating structure 52 influences the snapback characteristics, thus making it possible to set this characteristic. For example, it can be embodied as a recess partially filled with an insulating material, i.e. shallow trench insulation (STI). PECVD oxide is an example of an insulating material that can be used.

Located beneath the isolating structure 52 in a simple embodiment is semiconductor material 30 with a relatively high ohmic resistance. However, in order to adapt its ESD characteristics, it is preferred for the basic element 18 to have an additional layer 54 of the second conductivity type, with a higher dopant concentration than the semiconductor material 30, beneath the insulating structure 52 in the semiconductor material 30.

In order to provide a better understanding, the following explanation assumes a p-type conductivity as the first conductivity type and an n-type conductivity as the second conductivity type. Located beneath the p-doped anode regions 20, 22 is an n-doped extension layer 56, 58, which in each case is more highly doped than the n-layer 54. The cathode region 24, which has regionally n-doped semiconductor material 59, is delimited on both sides in the direction 32 by p-doped regions 60 and 61, which are located in an n-doped well 62 in the less heavily n-doped layer 54. The p-doped regions 60 and 61 are short-circuited with the n-doped semiconductor material 59 of the cathode region 24 by the sections 44 of the first wiring level 34. The n-doped semiconductor material 59 is thus located together with the p-doped regions 60 and 61 in the well 62 of n-doped semiconductor material, wherein the anode regions 20, 22 and the well 62 are connected by a semiconductor region 54 with ohmic conductivity of the second conductivity type (n) located between the buried dielectric layer 50 and the anode region 20, 22 and the well 62.

The basic element 18 described thus far in principle represents a lateral, bipolar pnp transistor with base regions 59 and emitter regions 60, 61 that are short-circuited by the second electrically conductive section 44 of the first wiring level 34, and with a collector 20, 22. The n-well 62 represents the base doping of the lateral pnp transistor. When the voltage of the anode regions 20, 22 becomes more negative than the voltage of the cathode region 24 due to an ESD pulse, as the ESD voltage increases the pn junction between the anode regions 20, 22 and the layers 56, 58 located below them is initially blocked until breakdown occurs between the anode regions 20, 22 acting as collector and the layers 56, 58 located below them, as a result of internal field forces in conjunction with an avalanche-like carrier increase. The breakdown results in a current through the semiconductor layer 54 and the regions 59, 62 functioning as base (avalanche effect).

Because of the common connection of base (regions 59, 62) and emitter (regions 60, 61) of the lateral pnp transistor, the basic element 18 initially does not exhibit transistor behavior.

As the current increases between base (regions 59, 62) and collector (anode regions 20, 22), a voltage drop takes place along a resistance path in the n-well 62 beneath the emitter regions 60, 61. When the value of this voltage drop exceeds an activation voltage U_{B}, the base-emitter junction is polarized in the forward direction. This leads to an injection of minority charge carriers from the emitter regions 60, 61 into the n-well 62 serving as base dopant, and thus to a “switching” of the basic element 18 to a low-resistance state that is associated with a voltage reduction (snapback; c.f. FIG. 3) and an increased current on account of the additional diffusion current between emitter 60, 61 and collector 20, 22, causing the current-carrying capacity of the structure to increase approximately by a factor of five.

The comparatively highly n-doped layers 56, 58 provided beneath the anode regions 20, 22 represent a breakdown doping, and serve to adapt the clamp voltage, which is to say the limiting voltage for external circuit measures. Moreover, without this doping the semiconductor structure of the basic element 18 could break down at the edges of the highly doped p⁺ anode regions 20, 22 on account of local field increases, which would limit the current that could be carried and/or could result in damage to the basic element 18.

FIG. 3 shows a characteristic curve 64 of a single basic element 18, in which the collector current I_{C} is plotted over the collector-emitter voltage U_{CE}. The collector current I_{C} rises sharply after reaching the breakdown voltage U_{D}, then levels out for a time. This corresponds to the avalanche breakdown described. With a further rise in the voltage, the current continues to rise shallowly until the described transistor switches to the low-resistance state at the snapback point 66. The snapback point, which is to say the pair of current and voltage values at which the base-emitter junction becomes conductive, can be set by varying the width of the emitter regions 60, 61, but also by changing the width of the STI insulation 52, wherein the STI insulation may also be omitted.

As is obvious to one skilled in the art, a semiconductor structure corresponding to the basic element 18 but with complementary doping instead (n instead of p and vice versa) serves to protect against a discharge with reversed polarity.

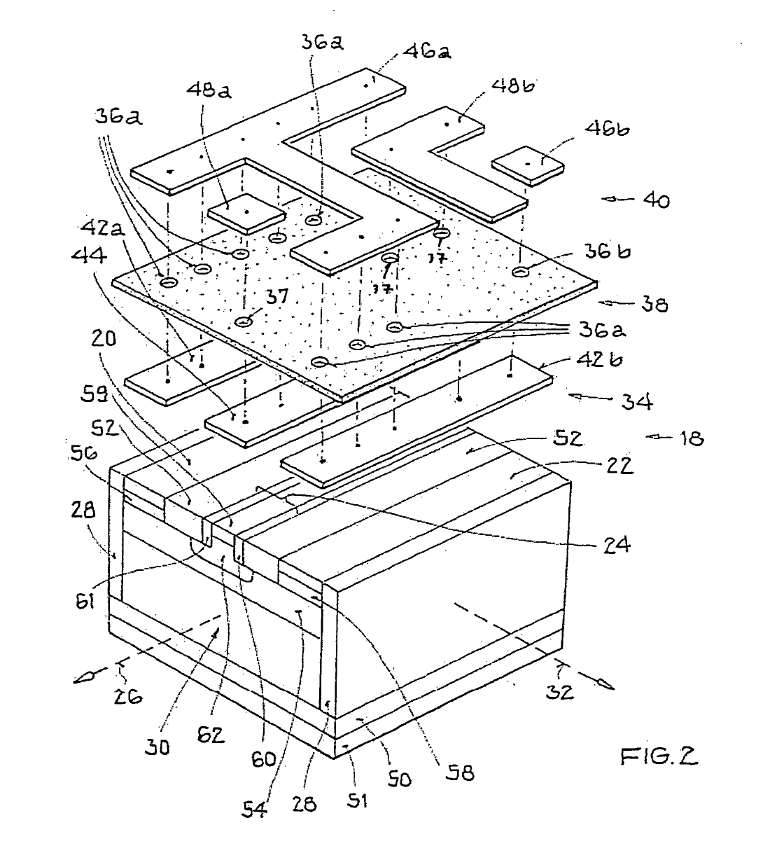

FIG. 4 shows a matrix 67 of n=4 rows and m=3 basic elements 18 each with the second wiring level 40 and with additional edge elements 68, which terminate each row. The edge elements 68 have, in particular, semicircular anode regions (not shown in detail) for the transitionless connection of the anode regions 20, 22 of a basic element 18 at the beginning and end of each row. The semicircular anode regions are also located within a component box composed of the buried dielectric layer 50 and the vertical isolating structures 28 from FIG. 2, so that the semiconductor regions of the individual rows are completely insulated from the semiconductor regions of adjacent rows, and are only connected to one another in a defined manner through the second wiring level 40.

With this dielectric insulation of the rows based on SOI technology, individual rows of the described matrix 67 can be combined with selectable values of the row count n and the column count m such that the voltage capacity of the rows scales with the number of rows. The characteristic curve of such a matrix can be mapped onto the characteristic curve of a single basic element 18 shown in FIG. 3, wherein the scaling of the voltage axis changes with the number of rows, and the scaling of the current axis changes with the number of basic elements per row. In particular, the snapback voltage value is very nearly proportional to the number of rows.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An ESD protection circuit having semiconductor structures as basic elements whose electrical conductivity changes in a breakdown or avalanche manner when an applied voltage exceeds a threshold value, the ESD protection circuit having a matrix of basic elements in which a desired current capacity is set by specifying a number of basic elements in each row of the matrix, and a desired voltage capacity is set by specifying a number of rows of the matrix.

2. The ESD protection circuit according to claim 1, wherein the matrix is an integrated circuit or is a portion of an integrated circuit.

3. The ESD protection circuit according to claim 1, wherein each basic element has at least one anode region and a cathode region, each having predefined dimensions, each anode region being formed of a semiconductor material of a first conductivity type, each cathode region being formed of a semiconductor material of a second conductivity type, wherein anode regions of the basic elements of a row join one another with no transition, wherein cathode regions of a row join one another with no transition, and wherein the semiconductor material of each row is insulated by a dielectric isolating structure from semiconductor material of each adjacent row.

4. The ESD protection circuit according to claim 3, wherein, parallel to each cathode region, two anode regions formed of the same basic element are arranged on two of its sides, and wherein each basic element of each row that is not located between two other basic elements is bordered on one side by an edge element that connects the two anode regions of the basic element to one another with no transition through an anode region of the same conductivity type.

5. The ESD protection circuit according to claim 3, wherein a first wiring level with a first electrically conductive area areally contacts the anode regions of each row, and a second electrically conductive area that is insulated from the first electrically conductive area areally contacts the cathode regions of each row.

6. The ESD protection circuit according to claim 5, wherein a second wiring level, which is areally isolated from the first wiring level by a dielectric intermediate layer, has electrically separated first sections and second sections, wherein the first sections are locally connected to the first electrically conductive area by openings in the dielectric intermediate layer filled with electrically conductive material, and the second sections are locally connected to the second electrically conductive area by openings that are filled with electrically conductive material.

7. The ESD protection circuit according to claim 6, wherein a buried dielectric layer dielectrically insulates the matrix on a side opposing the wiring levels.

8. The ESD protection circuit according to claim 7, wherein the dielectric isolating structures abut the buried dielectric layer.

9. The ESD protection circuit according to claim 7, wherein the anode regions and the cathode regions of a row are isolated from one another by a dielectric isolating structure that does not abut the buried dielectric layer.

10. The ESD protection circuit according to claim 9, wherein the cathode region is located in a well made of semiconductor material of the second conductivity type, wherein located in the well on a side facing the anode is at least one region of the first conductivity type that is connected to the second electrically conductive area of the first wiring level in common with semiconductor material of the second conductivity type, and wherein the anode region and well are connected by a semiconductor region with ohmic conductivity of the second conductivity type that is located between the buried dielectric layer and the anode region and the well.
